(19) United States
(12) Patent Application Publication
(10) Pub. No.: US 2021/0050867 A1
(43) Pub. Date: Feb. 18, 2021

(54) TRANSMITTING APPARATUS AND METHOD FOR CONTROLLING THE TRANSMITTING APPARATUS

(71) Applicant: SAMSUNG ELECTRONICS CO., LTD., Suwon-si (KR)

(72) Inventor: Yunkyoung HAN, Suwon-si (KR)

(73) Assignee: SAMSUNG ELECTRONICS CO., LTD., Suwon-si (KR)

(21) Appl. No.: 16/985,318

(22) Filed: Aug. 5, 2020

(30) Foreign Application Priority Data
Aug. 13, 2019 (KR) 10-2019-0098978

(51) Int. Cl. H03M 13/35; H04L 1/00; H04L 1/08; H04L 29/06; H03M 13/11; H03M 13/00

(52) U.S. Cl. CPC H03M 13/353; H04L 1/0061; H04L 1/0042; H03M 13/6393; H04L 65/608; H04L 1/0068; H03M 13/116; H04L 1/08

(57) ABSTRACT

A transmitting apparatus and a method of controlling the transmitting apparatus are provided. The transmitting apparatus includes an encoder; a transmitter; and a processor. The processor is configured to: control the encoder to generate repair symbols by performing encoding of source symbols based on information received from a receiving apparatus, and control the transmitter to transmit, to the receiving apparatus, the source symbols and at least some of the repair symbols. The information includes information indicating whether a decoding of symbols received from the receiving apparatus is successful, the symbols including the source symbols and the repair symbols, and a number of repair symbols transmitted to the receiving apparatus varies according to the decoding of the receiving apparatus being successful.

### CROSS-REFERENCE TO RELATED APPLICATION(S)

This application is based on and claims priority under 35 U.S.C. § 119 to Korean Patent Application No. 10-2019-0098978, filed on Aug. 13, 2019, in the Korean Intellectual Property Office, the disclosure of which is incorporated by reference herein in its entirety.

### BACKGROUND

### 1. Field

The disclosure relates to a transmitting apparatus and a method for controlling thereof, and more particularly, to a transmitting apparatus transmitting a packet and a method for controlling thereof.

### 2. Description of Related Art

An application layer forward error correction (AL-FEC) is a forward error correction (FEC) technique of an application layer for recovering lost packets during transmission. In general, unlike an automatic repeat request (ARQ) scheme that requires retransmission for packets lost at a receiver when a packet is lost, the AL-FEC recovers the lost packets by itself from the received packets using overhead packets received from a transmitting side, and therefore a delay (or latency) occurring at a transport layer is low.

MPEG-Dynamic Adaptive Streaming over HTTP (MPEG-DASH) technology is an adaptive bitrate streaming technology that enables high-quality streaming of media content on the Internet from an existing HTTP web server.

When the content is divided into small HTTP-based file segments, each segment may include pieces of the content, which may involve large reproduction time as a whole. The MPEG-DASH client automatically selects a next segment to be downloaded and reproduced according to a current network condition while the content is being reproduced. Thus, the MPEG-DASH client may smoothly adapt to changing network conditions and provide high quality reproduction with little or no stopping or re-buffering.

When a demand for high capacity multimedia services increases, for example, multiple viewers watching live streaming at the same time, network congestion may occur due to traffic, and packet loss may occur due to an increase in network load.

When many packet losses occur, many ARQ may occur and the network congestion may be aggravated. In the example of AL-FEC, ARQ may not be generated, but a fixed transmission overhead may be generated. Thus, if the congestion is low, available network resources may be unused or wasted in a fixed manner.

In the MPEG-DASH, a scene delay for tens of seconds may be generated as compared to terrestrial broadcasting, and there is a problem that it is vulnerable to live streaming. This delay is attributable to the encoding in segment units and the buffering policy in accordance with packet retransmission.

Accordingly, there is a need to achieve a more efficient transmission efficiency.

### SUMMARY

In accordance with an aspect of the disclosure, there is provided a transmitting apparatus including an encoder; a transmitter; and a processor. The processor is configured to: control the encoder to generate repair symbols by performing encoding of source symbols based on information received from a receiving apparatus, and control the transmitter to transmit, to the receiving apparatus, the source symbols and at least some of the repair symbols. The information includes information indicating whether a decoding of symbols received from the receiving apparatus is successful, the symbols including the source symbols and the repair symbols, and a number of repair symbols transmitted to the receiving apparatus varies according to the decoding of the receiving apparatus being successful.

The encoder is configured to encode the source symbols based on a quasi-cyclic low density parity check (QC-LDPC) code having a code rate determined based on a parameter, the transmitter is configured to transmit, to the receiving apparatus, the source symbols and the at least some repair symbols left after performing a puncturing, and the processor is further configured to: determine the parameter based on the information, and control the encoder to perform the encoding based on the determined parameter, determine a number of symbols to be punctured based on the information, and perform the puncturing based on the determined number of symbols to be punctured.

The processor is further configured to: based on the decoding at the receiving apparatus being successful, determine the parameter and the number of symbols to be punctured so that a second number of the at least some repair symbols to be transmitted to the receiving apparatus is less than a first number of the at least some repair symbols, the first number of the at least some repair symbols being transmitted prior to the second number of the at least some repair symbols, and based on the decoding at the receiving apparatus failing, determine the parameter and the number of symbols to be punctured so that the second number of the at least some repair symbols to be transmitted to the receiving apparatus is greater than the first number of the at least some repair symbols.

The receiving apparatus is configured to decode the symbols received from the transmitting apparatus based on a first decoding algorithm, and based on the first decoding algorithm of the receiving apparatus failing to decode at least one symbol among the symbols, decode the at least one symbol based on a second decoding algorithm having a relatively superior performance than the first decoding algorithm, and transmit, to the transmitting apparatus, the information indicating whether at least one of the first decoding algorithm or the second decoding algorithm is successful in the decoding.

The processor is further configured to: based on the decoding based on the first decoding algorithm being successful, identify whether a number of symbols punctured in previous symbols satisfies a predetermined first condition, and based on determining that the predetermined first condition is satisfied, determine the parameter and a number of symbols to be punctured for current symbols, and wherein the predetermined first condition is a value obtained by summing the number of symbols punctured in the previous symbols and a predetermined value that is greater than a maximum number of puncturable symbols.

The processor is further configured to: based on the predetermined first condition being satisfied, determine the parameter so that the code rate is higher than a code rate of the previous symbols, and set the number of symbols to be punctured to zero, and based on the predetermined first condition not being satisfied, determine the parameter so that the code rate is lower than the code rate of the previous symbols and determine the number of symbols to be punctured to be larger than the number of symbols punctured in the previous symbols.

The processor is further configured to: based the first decoding algorithm and the second decoding algorithm failing, identify whether a number of symbols punctured in previous symbols satisfies a predetermined second condition, and determine the parameter and the number of symbols to be punctured based on whether the predetermined second condition is satisfied, and the predetermined second condition is a value obtained by subtracting a predetermined value from the number of symbols punctured in the previous symbols.

The processor is further configured to: based on the predetermined second condition being satisfied, determine the parameter so that the code rate is lower than a code rate of the previous symbols, determine a maximum number of puncturable symbols defined according to the determined parameter as the number of symbols to be punctured, and based on the predetermined second condition not being satisfied, determine the number of symbols to be punctured to be fewer than the number of symbols punctured in the previous symbols.

The processor is further configured to, based on decoding based on the first decoding algorithm failing and decoding based on the second decoding algorithm being successful, control the encoder to perform encoding based on a parameter which is identical to a parameter used in previous symbols and determine a number of symbols to be punctured in a same manner as the previous symbols.

The parameter includes a row splitting coefficient defined in the QC-LDPC code.

In accordance with an aspect of the disclosure, there is provided a method for controlling a transmitting apparatus. The method includes: receiving information from a receiving apparatus; generating repair symbols by performing encoding of source symbols based on the received information; and transmitting, to the receiving apparatus, the source symbols and at least some of the repair symbols, wherein the received information includes information indicating whether a decoding of symbols received from the receiving apparatus is successful, the symbols including the source symbols and the repair symbols, and wherein a number of repair symbols transmitted to the receiving apparatus varies according to the decoding of the receiving apparatus being successful.

The method further includes: performing puncturing of the repair symbols, wherein the generating the repair symbols includes determining a parameter based on the received information, and encoding the source symbols based on a quasi-cyclic low density parity check (QC-LDPC) code having a code rate determined based on the parameter, wherein the performing the puncturing includes determining a number of symbols to be punctured based on the received information, and performing puncturing based on the determined number of symbols to be punctured, and wherein the transmitting includes transmitting, to the receiving apparatus, the source symbols and the at least some repair symbols left after performing the puncturing.

The generating the repair symbols further includes, based on the decoding at the receiving apparatus being successful, determining the parameter and the number of symbols to be punctured so that a second number of the at least some repair symbols to be transmitted to the receiving apparatus is less than a first number of the at least some repair symbols, the first number of the at least some repair symbols being transmitted to the receiving apparatus prior to the second number of the at least some repair symbols, and based on the decoding at the receiving apparatus failing, determining the parameter and the number of symbols to be punctured so that the second number of the at least some repair symbols to be transmitted to the receiving apparatus is greater than the first number of the at least some repair symbols.

The receiving apparatus is configured to: decode the symbols received from the transmitting apparatus based on a first decoding algorithm, and based on the first decoding algorithm of the receiving apparatus failing to decode at least one symbol among the symbols, decode the at least one symbol based on a second decoding algorithm having a relatively superior performance than the first decoding algorithm, and transmit, to the transmitting apparatus, the information indicating whether at least one of the first decoding algorithm or the second decoding algorithm is successful in the decoding.

The method further includes: based on the decoding based on the first decoding algorithm being successful, identifying whether a number of symbols punctured in previous symbols satisfies a predetermined first condition, wherein the predetermined first condition is a value obtained by summing the number of symbols punctured in the previous symbols and a predetermined value that is greater than a maximum number of puncturable symbols.

The generating the repair symbols further includes, based on the predetermined first condition being satisfied, determining the parameter so that the code rate is higher than a code rate of the previous symbols, and based on the predetermined first condition not being satisfied, determining the parameter in a same manner as the previous symbols, wherein the performing puncturing includes, based on the predetermined first condition being satisfied, setting the number of symbols to be punctured to zero, and based on the predetermined first condition not being satisfied, determining the number of symbols to be punctured to be larger than the number of symbols punctured in the previous symbols.

The method further includes: based on the first decoding algorithm and the second decoding algorithm failing to decode the symbols, identifying whether a number of symbols punctured in previous symbols satisfies a predetermined second condition, wherein the predetermined second condition is a value obtained by subtracting a predetermined value from the number of symbols punctured in the previous symbols.

The generating the repair symbols further includes, based on the predetermined second condition being satisfied, determining the parameter so that the code rate is lower than a code rate of the previous symbols, and wherein the performing puncturing includes, based on the predetermined second condition being satisfied, determining a maximum number of puncturable symbols defined according to the determined parameter as the number of symbols to be punctured and based on the predetermined second condition not being satisfied, determining the number of symbols to be punctured to be less than the number of symbols punctured in the previous symbols.

The generating the repair symbols further includes, based on decoding based on the first decoding algorithm failing and decoding based on the second decoding algorithm being successful, performing the encoding based on a parameter which is identical a parameter used in previous symbols, and wherein the performing puncturing includes, based on decoding based on the first decoding algorithm failing and decoding based on the second decoding algorithm being successful, determining a number of symbols to be punctured in a same manner as the previous symbols.

The parameter includes a row splitting coefficient defined in the QC-LDPC code.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a block diagram illustrating a configuration of a transmitting apparatus according to an embodiment;

FIG. 2 is a block diagram illustrating a detailed configuration of a transmitting apparatus according to an embodiment;

FIG. 3 is a block diagram illustrating a configuration of a receiving apparatus according to an embodiment;

FIG. 4 is a diagram illustrating a decoding method according to an embodiment; and

FIG. 5 is a flowchart illustrating an operation of a receiving apparatus according to an embodiment;

FIG. 6 is a block diagram illustrating a detailed configuration of a receiving apparatus according to an embodiment; and

FIG. 7 is a flowchart illustrating a method for controlling a transmitting apparatus according to an embodiment.

### DETAILED DESCRIPTION

Hereinafter, embodiments of the disclosure will be described with reference to the accompanying drawings. However, it may be understood that the disclosure is not limited to the embodiments described hereinafter, but may include various modifications, equivalents, and/or alternatives of the embodiments of the disclosure. In relation to the description of the drawings, similar drawing reference numerals may be used for similar constituent elements.

In the description, the term “has,” “may have,” “includes” or “may include” indicates existence of a corresponding feature (e.g., a numerical value, a function, an operation, or a constituent element such as a component), but does not exclude existence of an additional feature.

The term “A or B,” “at least one of A and/or B,” or “one or more of A or/and B” may include all possible combinations of the items that may be enumerated. For example, the term “at least one of A and/or B” may include (1) at least one A, (2) at least one B, or (3) both at least one A and at least one B.

The terms “first, second, and so forth” may be used to describe different elements regardless of their order and/or importance and to distinguish one element from another.

When an element (e.g., first element) is “operatively or communicatively coupled with/to” or is “connected to” another element (e.g., second element), it may be understood that the element may be connected to the other element directly or through still another element (e.g., third element). When one element (e.g., first element) is “directly coupled” with or “directly connected to” another element (e.g., second element), it may be understood that there is no element (e.g., third element) present between the element and the other element.

The expression “configured to” may be used interchangeably with, for example, “suitable for”, “having the capacity to”, “designed to”, “adapted to”, “made to”, or “capable of”. The expression “configured to” does not necessarily mean “specifically designed to” in a hardware sense. Instead, under some circumstances, “a device configured to” may indicate that such a device can perform an operation along with another device or part. For example, the expression “a processor configured to perform A, B, and C” may indicate an exclusive processor (e.g., an embedded processor) to perform the corresponding operation, or a generic-purpose processor (e.g., a central processor (CPU) or application processor (AP)) that can perform the corresponding operations by executing one or more software programs stored in the memory device.

The disclosure provides a transmitting apparatus for adaptively adjusting the number of repair symbols transmitted to a receiving apparatus according to whether the decoding of the receiving apparatus is successful and a method for controlling thereof.

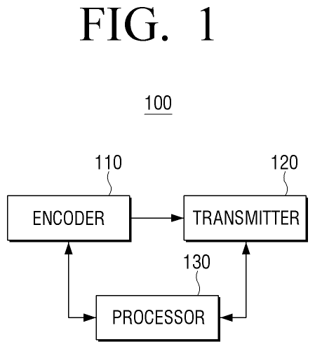

FIG. 1 is a block diagram illustrating a configuration of a transmitting apparatus according to an embodiment.

Referring to FIG. 1, a transmitting apparatus 100 may include an encoder 110, a transmitter 120, and a processor 130.

The transmitting apparatus 100 may include various transmitting apparatuses operated by a content provider providing content (e.g., a broadcasting content).

The encoder 110 may generate repair symbols (or parity symbols) by encoding source symbols (or information symbols).

The encoder 110 may encode the source symbols based on a quasi-cyclic low density parity check (QC-LDPC) code with a code rate determined based on the parameter, and may generate repair symbols.

Here, the QC-LDPC code may include a structured low density parity check (S-LDPC) code. The S-LDPC code is one of the MPEG media transport (MMT) application layer forward error correction (AL-FEC) specifications.

In an example, the encoder 110 may apply scaling, row splitting, puncturing, or the like, to a base matrix and generate a parity check matrix having various sizes and code rates, and may perform encoding using a parity check matrix.

For this purpose, the QC-LDPC code may define a parameter. Herein, the parameter may include a scaling down factor S₁ and a row splitting coefficient S₂.

For example, if the size of the base matrix is 320×6720, a parity check matrix having a size of (n−k)×n, that is, (S₂×320/S₁)×((6400+S₂×320)/S₁) may be generated from the base matrix according to S₁ and S₂. In this example, the code length n according to the parity check matrix is n=(6400+S₂×320)/S₁, and the number k of the source symbols may be k=6400/S₁.

Table 1 below represents the code length n of the QC-LDPC code n and the number of source symbols k according to S₁ and S₂.

TABLE 1

| S1 | S2 | n | k | overhead | code rate | max_Np |
|---|---|---|---|---|---|---|
| 1 | 1 | 6720 | 6400 | 320 | 0.95 | 320 |
| 1 | 2 | 7040 | 6400 | 640 | 0.91 | 319 |
| 1 | 4 | 7680 | 6400 | 1280 | 0.83 | 639 |
| 1 | 8 | 8960 | 6400 | 2560 | 0.71 | 1279 |
| 1 | 16 | 11520 | 6400 | 5120 | 0.56 | 2559 |
| 2 | 1 | 3360 | 3200 | 160 | 0.95 | 160 |
| 2 | 2 | 3520 | 3200 | 320 | 0.91 | 159 |
| 2 | 4 | 3840 | 3200 | 640 | 0.83 | 319 |
| 2 | 8 | 4480 | 3200 | 1280 | 0.71 | 639 |
| 2 | 16 | 5760 | 3200 | 2560 | 0.56 | 1279 |
| 4 | 1 | 1680 | 1600 | 80 | 0.95 | 80 |
| 4 | 2 | 1760 | 1600 | 160 | 0.91 | 79 |
| 4 | 4 | 1920 | 1600 | 320 | 0.83 | 159 |
| 4 | 8 | 2240 | 1600 | 640 | 0.71 | 319 |
| 4 | 16 | 2880 | 1600 | 1280 | 0.56 | 639 |
| 8 | 1 | 840 | 800 | 40 | 0.95 | 40 |
| 8 | 2 | 880 | 800 | 80 | 0.91 | 39 |
| 8 | 4 | 960 | 800 | 160 | 0.83 | 79 |
| 8 | 8 | 1120 | 800 | 320 | 0.71 | 159 |
| 8 | 16 | 1440 | 800 | 640 | 0.56 | 319 |
| 16 | 1 | 420 | 400 | 20 | 0.95 | 20 |
| 16 | 2 | 440 | 400 | 40 | 0.91 | 19 |
| 16 | 4 | 480 | 400 | 80 | 0.83 | 39 |
| 16 | 8 | 560 | 400 | 160 | 0.71 | 79 |
| 16 | 16 | 720 | 400 | 320 | 0.56 | 159 |

In Table 1, the overhead represents the number of repair symbols n−k generated by encoding, and the code rate is k/n.

The max_Np denotes the number of symbols for which puncturing is allowable to the maximum when puncturing is performed on the repair symbols (hereinafter, the maximum number of puncturable symbols), and max_Np may be determined according to Equation 1 below.

$$\begin{matrix}max\_Np = n - k & if {S}_{2} = 1 \\ ( n - k ) \text{/} 2 - 1 & otherwise\end{matrix} \qquad [ Equation 1 ]$$

Here, n refers to the code length and k refers to the number of source symbols.

As shown in Table 1, a parity check matrix having various sizes and code rates may be generated according to S₁ and S₂. Accordingly, the encoder 110 may use the parity check matrix to encode the source symbols according to various code rates to generate repair symbols. The code rate may be determined according to S₁ and S₂.

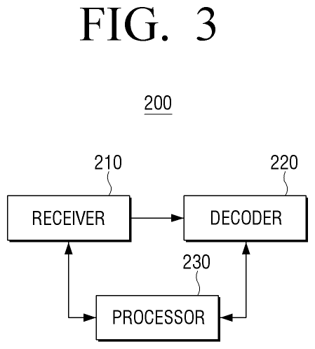

Performing encoding using which S₁ and S₂ values may be determined or adjusted according to information received from a receiving apparatus (shown in FIG. 3), and the details are described below.

The transmitter 120 may transmit source symbols and at least some of the repair symbols generated by encoding to a receiving apparatus.

The transmitter 120 may include an antenna, or the like.

At least some of the repair symbols may be transmitted to a receiving apparatus, and the left repair symbols may not be transmitted to a receiving apparatus. Specifically, the punctured symbols among the repair symbols may not be transmitted to a receiving apparatus.

The transmitter 120 may transmit, through a packet, the source symbols and repair symbols left after the puncturing to the receiving apparatus.

The symbol may configure a payload of the packet, and the packet header may include information on the symbols included in the payload and information on the parameters (that is, S₁ and S₂) used in encoding the corresponding symbol.

The information on the symbol may include source block number (SBN) and encoding symbol ID (ESI).

Specifically, the encoder 110 may encode the k source symbols to generate n−k repair symbols. In this example, k source symbols and n−k repair symbols may form one codeword.

The SBN may refer to an index which symbols included in one codeword may have in common, and the ESI may refer to an index for each of a plurality of symbols forming one codeword.

For example, the number of source symbols to be transmitted to the receiving apparatus may be 2×k.

The encoder 110 may generate n−k repair symbols (p₀, p₁, . . . , pₙ₋ₖ₋₁) by encoding k source symbols (i₀, i₁, . . . , iₖ₋₁). In this example, the codeword may be (i₀, i₁, . . . , iₖ₋₁, p₀, p₁, . . . , pₙ₋ₖ₋₁).

The SBN of the source symbols and the repair symbols included in the corresponding codeword may be 0.

The symbols (i₀, i₁, . . . , iₖ₋₁, p₀, p₁, . . . , pₙ₋ₖ₋₁) constituting the codeword may be indexed sequentially, so that the ESI of each symbol may be determined. That is, the ESI of i₀ may be 0, the ESI of i₁ may be 1 . . . , and the ESI of pₙ₋ₖ₋₁ may be n−1.

Here, (SBN, ESI) of i₀ is (0, 0), (SBN, ESI) of i₁ is (0, 1) . . . , and (SBN, ESI) of pₙ₋ₖ₋₁ is (0, n−1).

The encoder 110 may generate n−k repair symbols (p′₀, p′₁ . . . , p′ₙ₋ₖ₋₁) by encoding the following k source symbols (i′₀, i′₁ . . . , i′ₖ₋₁). In this example, the next codeword may be (i′₀, i′₁ . . . i′ₖ₋₁, p′₀, p′₁ . . . , p′ₙ₋ₖ₋₁).

The SBN of the source symbols and the repair symbols included in the codeword may be 1.

The symbols (i′₀, i′₁, . . . , i′ₖ₋₁, p′₀, p′₁, . . . , p′ₙ₋ₖ₋₁) constituting the codeword may be sequentially indexed, respectively, and the ESI of each symbol may be determined. That is, the ESI of i′₀ may be 0, the ESI of may be 1, and the ESI of p′ₙ₋ₖ₋₁ may be n−1.

The (SBN, ESI) of i′₀ may be (1, 0), (SBN, ESI) of i′₁ may be (1, 1), . . . , and (SBN, ESI) of p′ₙ₋ₖ₋₁ may be (1, n−1).

According to the above method, the SBN and the ESI for each symbol may be determined.

The processor 130 may control the overall operation of the transmitting apparatus 100. Specifically, the processor 130 may control the encoder 110 to perform encoding on the source symbols based on information received by the receiver from a receiving apparatus to generate repair symbols, and transmit one or more of the source symbols and the repair symbols to a receiving apparatus through the transmitter 120.

The information received from the receiving apparatus may include information on whether decoding of symbols received at the receiving apparatus is successful. In this example, the number of repair symbols transmitted to the receiving apparatus may vary depending on whether the receiving apparatus successfully decodes the received symbols.

The receiving apparatus may decode the symbols received from the transmitting apparatus 100, and if the decoding succeeds, the receiving apparatus may transmit, to the transmitting apparatus 100, information indicating that the decoding was successful. However, if the decoding fails, the receiving apparatus may transmit, to the transmitting apparatus 100, information indicating that the decoding failed.

Based on the information received from the receiving apparatus, the processor 130 may determine whether decoding is successful at a receiving apparatus and may determine the number of symbols to be transmitted to the receiving apparatus according to the success or failure of decoding.

The processor 130 may determine a parameter used for encoding based on the received information, determine the number of repair symbols that are punctured based on the received information, and control encoding and puncturing to be performed based thereon.

The processor 130 may determine a parameter based on information received from a receiving apparatus and control the encoder 110 to perform encoding based on the determined parameter. The processor 130 may determine the number of symbols to be punctured based on the information received from the receiving apparatus, and perform puncturing based on the determined number.

Depending on the success of decoding of the receiving apparatus, the number of punctured symbols and parameters may vary.

When decoding is successful in the receiving apparatus, the processor 130 may determine a parameter and the number of symbols to be punctured so that the number of repair symbols to be transmitted to the receiving apparatus is less than the number of repair symbols transmitted before, and if the decoding at the receiving apparatus fails, the processor 130 may determine the number of symbols to be punctured and the parameter so that the number of repair symbols to be transmitted to the receiving apparatus is greater than the number of repair symbols transmitted before.

The transmitting apparatus 100 transmits overhead, that is, repair symbols, to a receiving apparatus so that a receiving apparatus may recover packets lost due to network congestion in a transmission process. If the transmitting apparatus 100 fixedly transmits repair symbols without considering the decoding success of the receiving apparatus, it is not appropriate in terms of transmission efficiency. Therefore, according to an embodiment, based on the decoding success of the receiving apparatus, the transmitting apparatus 100 may adaptively adjust the number of repair symbols to be transmitted to the receiving apparatus to increase transmission efficiency and effectively restore a packet at a receiving side through a minimum transmission overhead.

The receiving apparatus may decode symbols received from the transmitting apparatus 100 using a plurality of decoding algorithms.

Specifically, the receiving apparatus may decode the received symbols from the transmitting apparatus 100 based on a first decoding algorithm, and may decode the received symbols from the transmitting apparatus 100 based on a second decoding algorithm if the decoding based on the first decoding algorithm fails.

The second decoding algorithm may be decoding algorithm having a relatively superior performance than the first decoding algorithm.

For example, the first decoding algorithm may include an iterative decoding algorithm, and the second decoding algorithm may include a Gaussian elimination (GE) decoding algorithm. Here, the GE decoding algorithm has a higher computational complexity than the iterative decoding algorithm, but the decoding performance is superior.

That is, the receiving apparatus may perform decoding using the first decoding algorithm in consideration of computational complexity and decoding performance, and may perform decoding by using a second decoding algorithm when decoding using the first decoding algorithm fails.

In the example above, various decoding algorithms may be used in consideration of computational complexity and decoding performance.

The receiving apparatus may transmit information on the decoding success to the transmitting apparatus 100.

Specifically, the receiving apparatus may perform decoding on symbols received from the transmitting apparatus 100 using a first decoding algorithm, and transmit, to the transmitting apparatus 100, information on whether decoding is successful, i.e., whether the recovery of symbols is successful. When the decoding based on the first decoding algorithm fails, the receiving apparatus performs decoding on the symbols received from the transmitting apparatus 100 using the second decoding algorithm, and information on whether the decoding is successful may be transmitted to the transmitting apparatus 100.

The receiving apparatus may transmit not only information on the decoding success, but also other information to the transmitting apparatus 100.

For example, the receiving apparatus may transmit information on the number of symbols received from the transmitting apparatus 100, the SBN and the ESI of the decoded symbol, the parameters used in encoding the corresponding symbol (i.e., information on S1 and S2), to the transmitting apparatus 100.

The receiving apparatus may obtain information on SBN, ESI and parameters (that is, S₁ and S₂) from a packet header.

The receiving apparatus may obtain the symbol from the payload of the packet and perform decoding using the corresponding symbol, and the receiving apparatus may obtain information on the SBN, ESI and parameters (i.e., S₁ and S₂) of the corresponding symbol from the packet header of the packet.

The receiving apparatus may transmit the decoding success of the received symbols, information on SBN, ESI, and parameters (that is, S₁ and S₂) to the transmitting apparatus 100.

As described above, in addition to the information on whether the decoding is successful, transmitting the SBN, ESI, and parameters (i.e., S₁ and S₂) of the symbol to the transmitting apparatus 100 is to check whether the transmitting apparatus 100 performs encoding on the symbol using any parameter value and punctures how many symbols among the repair symbols generated according to the encoding of the corresponding symbol.

The transmitting apparatus 100 may determine a parameter to be used in encoding for the next source symbols based on information received from the receiving apparatus, and may also determine the number of symbols to be punctured upon puncturing the repair symbols generated by the encoding. The transmitting apparatus 100 may encode the source symbols according to the determined parameters to generate repair symbols, puncture repair symbols as many as the number determined among the generated repair symbols, and transmit the source symbols and the repair symbols left after the puncturing to a receiving apparatus.

The processor 130 may determine the codeword for which decoding is performed at the receiving apparatus based on the SBN received from the receiving apparatus, and upon puncturing of the codeword, the processor 130 may determine how many repair symbols are punctured.

The processor 130 may determine the maximum number of puncturable symbols defined in accordance with the QC-LDPC code used in the encoding of the symbol to which the decoding is performed, based on the parameters received from the receiving apparatus (i.e., S₁ and S₂).

Referring to Table 1, when S₁, S₂ is 1, 1, the maximum number of symbols puncturable in the QC-LDPC code where S₁=1, S₂=1 may be max_Np=320.

If decoding based on the first decoding algorithm is successful based on the information received from the receiving apparatus, the processor 130 may determine whether the number of previously punctured symbols satisfies a predetermined first condition, and may determine a parameter and the number of symbols to be punctured based on whether a predetermined first condition is satisfied.

The predetermined first condition may be a condition based on the number of maximum puncturable symbols.

Specifically, the predetermined first condition may be a condition in which a value obtained by summing the number of previously punctured symbols and a predetermined value (e.g., α) is greater than the maximum number of puncturable symbols. That is, the predetermined first condition may be Np+α>max_Np.

A predetermined value denotes a change unit of a punctured symbol (i.e., the number of symbols that are changed when changing the number of punctured symbols), and may be, for example, 8. However, this is only an example, and the predetermined value may be variously changed.

Accordingly, the processor 130 may determine the parameter so that the code rate is higher than before if the predetermined first condition is satisfied, and may determine the number of symbols to be punctured as zero.

Accordingly, the processor 130 redefines a parameter value so that the code rate is higher than before. For example, when the existing parameter value is (S₁, S₂), the processor 130 may determine the parameter as (S₁, S₂/2).

For example, based on the decoding by the first decoding algorithm being successful, α=8, S₁=8, S₂=4, and Np=72 symbols are punctured among the repair symbols of the codeword corresponding to SBN=4. In this example, when S₁=8 and S₂=4, the maximum number of symbols that can be punctured is max_Np=79.

In another example, the processor 130 may determine parameters as S₁=8 and S₂=2, and when 80(=Np+a)>79(=max_Np) is satisfied, the processor 130 may generate repair symbols by encoding next source symbols using QC-LDPC codes according to the determined parameters. That is, when S₁=8, S₂=2, since n=880, k=800, the processor 130 may use the parity check matrix according to S₁=8, S₂=2 to encode 800 source symbols to produce 80 repair symbols. The processor 130 may transmit 800 source symbols and 80 repair symbols to a receiving apparatus without performing puncturing on the 80 repair symbols.

Accordingly, when S₁=8, S₂=4, and Np=72, fewer repair symbols are transmitted to a receiving apparatus than when 800 source symbols and 88 repair symbols are transmitted to a receiving apparatus.

If the predetermined first condition is not satisfied, the processor 130 may determine the parameter to be identical as before, and may determine the number of symbols to be punctured so that more symbols are punctured than the previous number of symbols punctured.

The predetermined first condition not being satisfied denotes that, when considering the maximum number of puncturable symbols of the QC-LDPC code determined based on the parameter, it is possible to further puncture symbols by a predetermined value as compared to the number of previously punctured symbols.

Accordingly, if the predetermined first condition is not satisfied, the processor 130 may perform encoding on the source symbols using the same parameter as before, and determine the number of symbols to be punctured so that at least a predetermined value (e.g., alpha (α) of symbols are punctured.

For example, it is assumed that decoding by the first decoding algorithm is successful when α=8, S₁=8, S₂=4, and Np=64 symbols among the repair symbols of the codeword corresponding to SBN=3 are punctured. In this example, when S₁=8, S₂=4, the number of puncturable maximum symbols equals max_Np=79.

Furthermore, when the condition 72(Np+α)>79(=max_Np) is not satisfied, upon encoding the next source symbols, the processor 130 may determine that the parameter for encoding remains the same as before, but may puncture a greater number of symbols in the repair symbols generated by the encoding of the next source symbols. That is, the processor 130 may encode 800 source symbols using a parity check matrix according to S₁=8, S₂=4, which is same as before, to generate 160 repair symbols. The processor 130 may puncture 72 (=Np+α) symbols among 160 repair symbols, and may transmit 800 source symbols and 88 repair symbols to a receiving apparatus.

Accordingly, when S₁=8, S₂=4, Np=64, the less amount of repair symbols may be transmitted to the receiving apparatus than in a case where 800 source symbols and 96 repair symbols are transmitted to the receiving apparatus.

If the receiving apparatus is successful in the decoding of the symbols using the first decoding algorithm, it may mean that the network congestion is somewhat low. As such, the receiving apparatus is more likely to succeed in the decoding with fewer repair symbols than before, and the transmitting apparatus 100 may transmit a smaller amount of repair symbols to the receiving apparatus for a greater transmission efficiency.

If it is determined that the decoding based on the first decoding algorithm and the second decoding algorithm both failed, and the transmitting apparatus 100 receives such information from the receiving apparatus, the processor 130 may determine whether the number of previously punctured symbols satisfies a predetermined second condition and may determine the parameter and the number of symbols to be punctured based on determining that the predetermined second condition is satisfied.

The predetermined second condition may be based on the maximum number of puncturable symbols.

The predetermined second condition may be a condition in which a value which is obtained by subtracting a predetermined value (e.g., α) from the previously punctured symbols is less than 0. That is, the predetermined second condition may be Np−α<0.

The predetermined value denotes the change unit (upon changing the number of symbols to be punctured, the number of changed symbols) of the symbols to be punctured, and may be, for example, 8. However, this is merely an example, and the predetermined value may variously change.

When the predetermined second condition is satisfied, the processor 130 may determine the parameter so that the code rate becomes lower than before, and may determine the number of maximum puncturable symbols as the number of symbols to be punctured according to the determined parameter.

The processor 130 may redefine or update the parameter value so that the code rate is lower than before. For example, if the existing parameter value is (S₁, S₂), the processor 130 may determine the parameter as, for example, (S₁, S₂×2). The processor 130 may determine the maximum number of puncturable symbols of the QC-LDPC code determined based on the updated parameter as the number of symbols to be punctured.

For example, decoding based on the first decoding algorithm and the second decoding algorithm may fail when α=8, S₁=8, S₂=4, and Np=6 symbols among the repair symbols of the codeword corresponding to SBN=4 are punctured.

In this example, the processor 130 may determine a parameter as, for example, S₁=8, S₂=8, such that if a condition −2(=Np−α)<0 is satisfied, the processor 130 may encode the next source symbols using the QC-LDPC code according to the determined parameter to generate repair symbols. That is, when S₁=8, S₂=8, since n=1120, k=800, the processor 130 may use the parity check matrix according to S₁=8, S₂=8 to encode 800 source symbols to generate 320 repair symbols. When S₁=8 and S₂=8, the processor 130 may puncture 159 symbols out of 320 repair symbols, and may transmit 800 source symbols and 161 repair symbols to the receiving apparatus, as the maximum number of puncturable symbols is max_Np=159.

Accordingly, when S₁=8, S₂=4, Np=6, if 800 source symbols and 154 repair symbols are transmitted to a receiving apparatus, more repair symbols are transmitted to a receiving apparatus.

If the predetermined second condition is not satisfied, the processor 130 may determine the number of symbols to be punctured so that fewer symbols than before may be punctured.

Specifically, the predetermined second condition not being satisfied may denote that, when considering the number of previously punctured symbols, symbols less than the previously punctured symbols by a predetermined value may be punctured.

Thus, when the predetermined second condition is not satisfied, the processor 130 may determine the number of symbols to be punctured so that the symbols to be punctured are less than before by a predetermine value (e.g., α).

Accordingly, if the predetermined second condition is not satisfied, the processor 130 may perform encoding on the source symbols using the same parameter as before, and may determine the number of symbols to be punctured such that fewer symbols are punctured by a predetermined value than before.

For example, it is assumed that decoding based on the first decoding algorithm and the second decoding algorithm fail when α=8, S₁=8, S₂=4, and Np=10 symbols among repair symbols of the codeword corresponding to SBN=4 are punctured.

Here, when the processor 130 does not satisfy 2(=Np−α)<0, upon encoding the next source symbols, the parameter for encoding remains the same as before, but may further reduce the number of symbols to be punctured among the repair symbols generated by the encoding of the next source symbols. That is, the processor 130 may encode 800 source symbols using a parity check matrix according to S₁=8, S₂=4, as before, to generate 160 repair symbols. The processor 130 may puncture 2 (=Np−α) symbols among 160 repair symbols, and may transmit 800 source symbols and 158 repair symbols to a receiving apparatus (not shown).

Accordingly, when S₁=8, S₂=4, Np=64, more repair symbols may be transmitted to a receiving apparatus than when 800 source symbols and 150 repair symbols are transmitted to the receiving apparatus.

In other words, if the receiving apparatus fails to decode using the first decoding algorithm and the second decoding algorithm, it may be understood that the network congestion is somewhat high. In this example, the transmitting apparatus 100 transmits a greater amount of repair symbols to a receiving apparatus in that more repair symbols are required than before for the recovery of the lost packet.

The processor 130 may control the encoder 110 to perform encoding based on the same parameters as before, if the decoding based on the first decoding algorithm fails, but the decoding based on the second decoding algorithm is successful, and the processor 130 may determine the number of symbols to be punctured to be the same as before.

The processor 130 may perform encoding based on the same parameters as before, for the next source symbols, and may puncture the same number of symbols as before among the repair symbols generated by the encoding for the next source symbols. This is because decoding may be performed successfully through the second decoding algorithm, although it is not the first decoding algorithm, in the current receiving apparatus.

As described above, according to an embodiment, the transmitting apparatus 100 may adaptively change the number of repair symbols transmitted to the receiving apparatus according to the decoding success of the receiving apparatus. According to an embodiment, transmission efficiency may be improved by minimizing transmission overhead without generating a fixed overhead while applying AL-FEC.

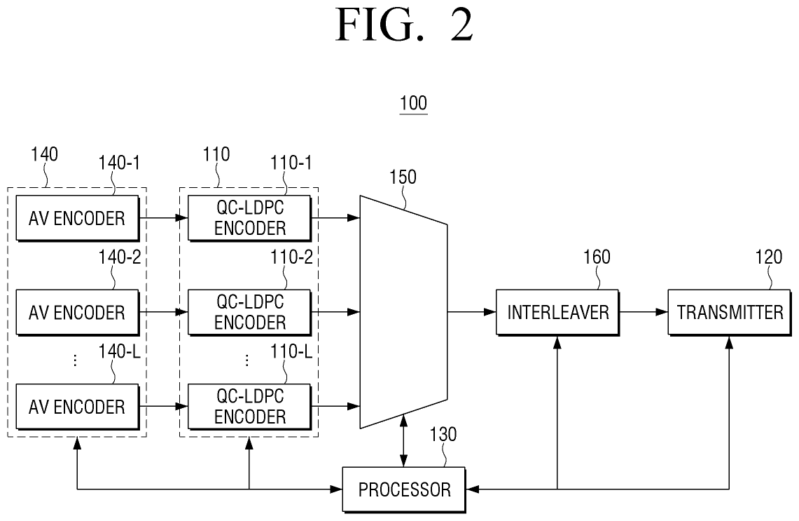

FIG. 2 is a block diagram illustrating a detailed configuration of a transmitting apparatus according to an embodiment.

Referring to FIG. 2, the transmitting apparatus 100 may include the first encoder 110, the transmitter 120, the processor 130, a second encoder 140, a MUX 150, and an interleaver 160.

The first encoder 110, the transmitter 120, and the processor 130 may be applied with the descriptions of the encoder 110, the transmitter 120, and the processor 130 described with respect to FIG. 1, and a repeating description thereof will be omitted.

The second encoder 140 may include a plurality of AV encoders 140-1, 140-2, . . . , 140-L. Each AV encoder may compress content (e.g., broadcasting content) using various codecs such as high efficiency video coding (HEVC), H.264, H.265, or the like.

The second encoder 140 includes a plurality of audio/video (AV) encoders 140-1, 140-2, . . . , 140-L. In this example, content having different resolutions, such as standard definition (SD), high definition (HD), Full HD, 4K-ultra HD (UHD), 8K-UHD, etc., may be input for each AV encoder. For example, a content having a resolution of 4K-UHD may be input to the AV encoder 140-1, and content having a resolution of 8K-UHD may be input to the AV encoder 140-2. Content having a resolution of full HD may be input to the AV encoder 140-L. Accordingly, the compressed contents output from each AV encoder may have different bit rates.

The first encoder 110 may include a plurality of QC-LDPC encoders 110-1, 110-2, . . . , 110-L.

In this example, each QC-LDPC encoder may perform the same function as the encoder 110 of FIG. 1. That is, each QC-LDPC encoder may generate repair symbols by encoding the source symbols using the QC-LDPC code, using the compressed content received from each AV encoder as source symbols. In this example, each QC-LDPC encoder may output a codeword composed of source symbols and repair symbols.

Here, the parameters S₁ and S₂ of the QC-LDPC code may be determined based on information received from the receiving apparatus, and may be controlled by the processor 130. The detailed description thereof has been described with reference to FIG. 1.

The MUX 150 may receive output of a plurality of QC-LDPC encoders 110-1, 110-2, . . . , 110-L, and may output one of the plurality of QC-LDPC encoders 110-1, 110-2, . . . , 110-L. A switching operation of the MUX 150 may be controlled by the processor 130.

The interleaver 160 may interleave codewords including source symbols and repair symbols input from the MUX 150.

The interleaver 160 may interleave the symbols included in the codeword based on a predetermined interleaving rule, and may output the interleaved codeword to the transmitter 120.

The processor 130 may puncture at least a part of the repair symbols included in the interleaved codewords.

In this example, the number of repair symbols punctured may be determined according to information received from a receiving apparatus, which may be controlled by processor 130. The detailed description thereof has been described with reference to FIG. 1.

The transmitter 120 may transmit, to the receiving apparatus, the source symbols and the repair symbols left after the puncturing.

The transmitter 120 may generate a packet by adding a packet header to each symbol, and transmit the plurality of generated packets to the receiving apparatus. The packet header may include information on the SBN and ESI of the symbol included in the packet, and the parameters S₁ and S₂ used in encoding the symbol.

FIG. 3 is a block diagram illustrating a configuration of a receiving apparatus according to an embodiment.

Referring to FIG. 3, a receiving apparatus 200 may include a receiver 210, a decoder 220, and a processor 230.

The receiving apparatus 200 may be, for example, a television (TV), a set-top box, or the like, capable of receiving content (e.g., broadcasting content).

The receiver 210 may receive a plurality of packets transmitted by the transmitting apparatus 100. In this example, each packet may include a payload and a packet header. Here, the payload may be composed of symbols, and the packet header may include information about the symbols included in the payload (i.e., SBN and ESI) and information about the parameters used in encoding (i.e., S₁ and S₂).

The receiver 210 may parse information on the SBN, ESI, S₁, and S₂ from the packet header of each packet.

The decoder 220 may perform decoding of symbols.

The decoder 220 may decode symbols based on the QC-LDPC code having a code rate determined based on parameters.

The decoder 220 may decode the symbols based on the first decoding algorithm.

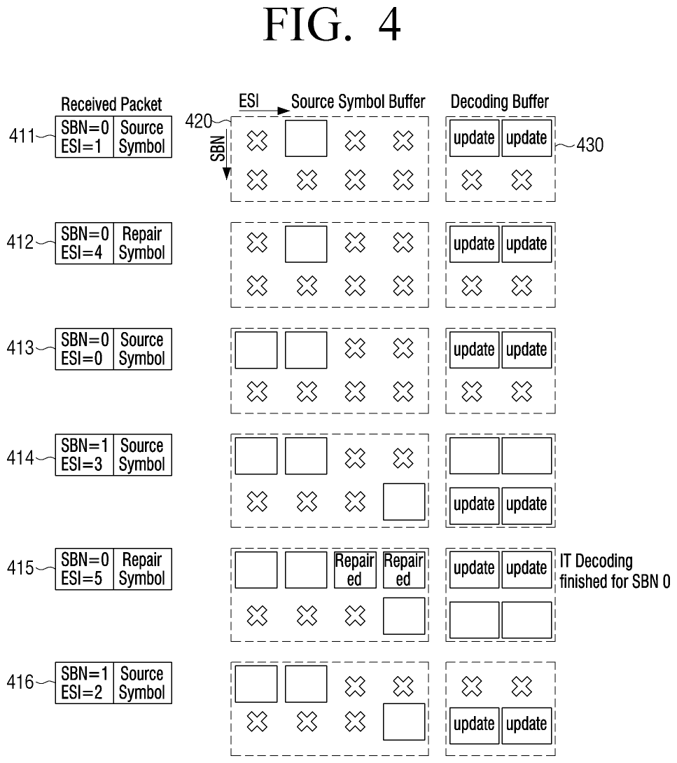

The first decoding algorithm may include an iterative decoding algorithm. Hereinafter, the decoding method based on the iterative decoding algorithm will be described with reference to FIG. 4.

FIG. 4 illustrates a method for performing iterative decoding using corresponding symbols when four packets for four source symbols and two repair packets for two repair symbols are received, according to an embodiment.

The receiving apparatus 200 may include a buffer for decoding, and the buffer may include a source symbol buffer 420 and a decoding buffer 430.

Referring to FIG. 4, the decoder 220 may store the source symbol in a location corresponding to the SBN and the ESI in the buffer, based on the SBN and the ESI of the source symbol. The decoder 220 may update the repair symbol by accumulating source symbols corresponding to a position of 1 of the parity check matrix of the QC-LDPC code defined according to the parameters S₁ and S₂, among the source symbols stored in the buffer. In this manner, the decoder 220 may perform iterative decoding to recover the lost source symbols in the transmission process.

For example, for a packet 411 including the source symbol, since SBN=0, ESI=1, the decoder 220 may store the source symbol of the packet 411 in the first column of the 0^{th} row of the buffer. In this example, if 1 exists at a position corresponding to SBN=0 and ESI=1 in the parity check matrix, the decoder 220 may update the repair symbol of the 0^{th} row using the source symbol stored in the 1^{st} column of the 0^{th} row of the buffer.

The packet 412 including the repair symbols, since SBN=0 and ESI=4, the decoder 220 may update the 4^{th} column of the 1^{st} row of the buffer using the repair symbol of the packet 411.

For the packet 413 including the source symbol, since SBN=0, ESI=0, the decoder 220 may store the source symbol of a packet 411 in the 0^{th} column of the 0^{th} row of the buffer. In this example, the decoder 220 may update the repair symbol stored in the 0^{th} row using the source symbol stored in the 0^{th} column of the 0^{th} row of the buffer when 1 is present in the parity check matrix corresponding to SBN=0, ESI=0.

The decoder 220 may perform the above process for packets 414, 415, and 416.

Referring to FIG. 4, if SBN=0, packets including source symbols with ESI=2, 3 have been lost in the transmission process. However, the decoder 220 may recover the source symbols corresponding to ESI=2, 3, through four packets including symbols that are ESI=0,1,4,5. As such, when decoding using the source symbols stored in one row is complete, the decoder 220 may output decoded symbols for that row. Accordingly, the row of buffers may be used again.

Consequently, the decoder 220 may perform the decoding through the above process and recover the source symbols.

The processor 230 may perform decoding based on the first decoding algorithm and may transmit information on a decoding performing result to the transmitting apparatus 100.

The processor 230 may transmit, to the transmitting apparatus 100, information indicating that decoding based on the first decoding algorithm is successful if all the lost symbols are recovered as a result of decoding based on the first decoding algorithm. The processor 230 may transmit, to the transmitting apparatus 100, information indicating that decoding based on the first decoding algorithm has failed when the lost symbol is not recovered as a result of decoding based on the first decoding algorithm.

The processor 230 may transmit, to the transmitting apparatus 100, information on the SBN of the symbol for which the decoding is performed and the parameters S₁ and S₂ used in the encoding of the corresponding symbol.

When decoding based on the first decoding algorithm fails, the decoder 220 may perform decoding on the symbols using the second decoding algorithm.

Here, the second decoding algorithm may include a Gaussian elimination (GE) decoding algorithm. In this case, the GE decoding algorithm has a higher computational complexity than the iterative decoding algorithm, but the decoding performance is more superior.

The processor 230 may transmit, to the transmitting apparatus 100, information on a result of the decoding performing based on the second decoding algorithm.

Specifically, the processor 230 may transmit, to the transmitting apparatus 100, information indicating that decoding based on the second decoding algorithm is successful if all the lost symbols are recovered as a result of decoding based on the second decoding algorithm. The processor 230 may transmit, to the transmitting apparatus 100, information indicating that decoding based on the second decoding algorithm fails when the lost symbol is not recovered as a result of decoding based on the second decoding algorithm.

The processor 230 may transmit, to the transmitting apparatus 100, information on the SBN of the symbol for which the decoding is performed and the information on the parameters S₁ and S₂ used in the encoding of the corresponding symbol.

The processor 230 may control the overall operation of the receiving apparatus 200. Specifically, the processor 230 may control the receiver 210 to obtain information about the symbols included in the payload from the received packet (i.e., SBN and ESI) and parameters used in encoding (i.e., S₁ and S₂), and control the decoder 220 to perform decoding using the symbols included in the received packet.

When decoding is performed by the decoder 220, the processor 230 may transmit information on whether the decoding is successful or information on the SBI, ESI of the symbol for which decoding is performed and parameters (that is, S₁ and S₂) to the transmitting apparatus 100.

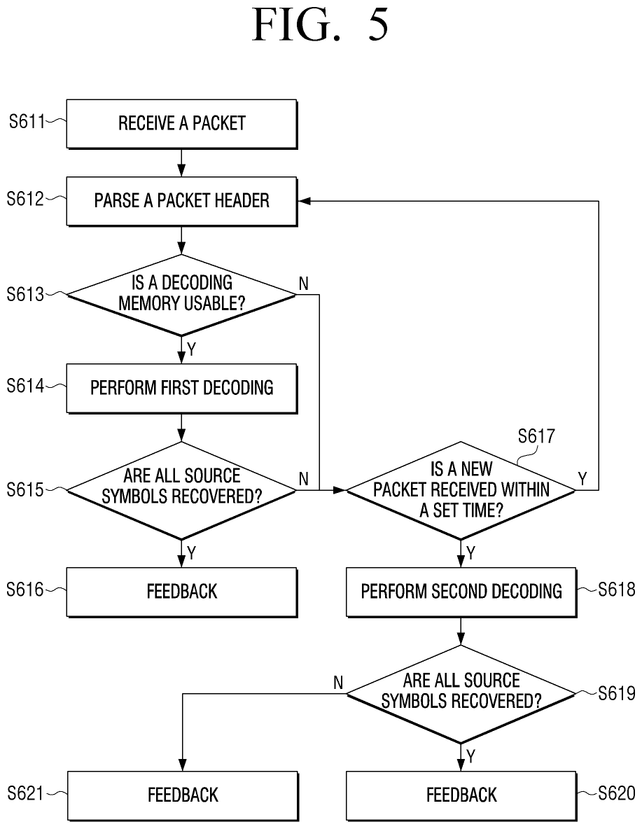

FIG. 5 is a flowchart illustrating an operation of a receiving apparatus according to an embodiment.

The receiving apparatus 200 may receive a packet from the transmitting apparatus 100 in operation S611.

The receiving apparatus 200 may parse information on the symbols included in the payload of the packet from the packet header of the received packet (i.e., SBN, ESI) and information about the parameters S₁ and S₂ used in encoding the symbol in operation S612.

The receiving apparatus 200 may determine whether the decoding memory or buffer is usable in operation S613.

When the buffer is usable in operation S613-Y, the receiving apparatus 200 may perform decoding using the first decoding algorithm in operation S614.

Specifically, when the received symbol is a source symbol, the receiving apparatus 200 may update the repair symbol by storing the source symbol in the buffer, and update the repair symbol using the received symbol when the received symbol is a repair symbol to perform decoding.

When there are lost symbols, the receiving apparatus 200 may determine whether all the lost symbols are recovered in operation S615.

When all the lost symbols are recovered in operation S615-Y, i.e., if the decoding based on the first decoding algorithm is successful, the receiving apparatus 200 may give a feedback to the transmitting apparatus 100 by transmitting information indicating the success of the decoding to the transmitting apparatus 100 in operation S616.

Specifically, the receiving apparatus 200 may transmit, to the transmitting apparatus 100, information indicating that the decoding based on the first decoding algorithm is successful, information on the SBN of the symbol for which decoding is performed, and information on S₁ and S₂.

If all the lost symbols are not recovered in operation S615-N, that is, if the decoding based on the first decoding algorithm fails, the receiving apparatus 200 may determine whether a new packet is received within a predetermined time.

The receiving apparatus 200 may perform the above process for a new packet when the new packet is received in operation S617-Y.

If a new packet is not received in operation S617-N, the receiving apparatus 200 may perform decoding using the second decoding algorithm in operation S618.

Thereafter, the receiving apparatus 200 may determine whether all the lost symbols are recovered.

When all the lost symbols are recovered in operation S619-Y, that is, if the decoding based on the second decoding algorithm is successful, the receiving apparatus 200 may provide feedback to the transmitting apparatus 100 according to operation S620.

That is, the receiving apparatus 200 may transmit, to the transmitting apparatus 100, information indicating that the decoding based on the second decoding algorithm is successful, information on the SBN of the symbol for which decoding is performed, and information on S₁ and S₂.

If all the lost symbols are not received in operation S619-N, that is, if the decoding based on the second decoding algorithm fails, the receiving apparatus 200 may provide feedback to the transmitting apparatus 100 according to operation S621.

Specifically, the receiving apparatus 200 may transmit, to the transmitting apparatus 100, information indicating that decoding based on the first decoding algorithm and the second decoding algorithm failed, information on SBN of the symbol for which decoding is performed, and the information on S₁ and S₂.

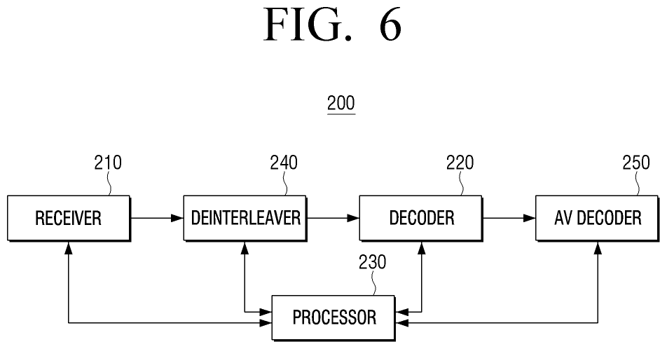

FIG. 6 is a block diagram illustrating a detailed configuration of a receiving apparatus according to an embodiment.

Referring to FIG. 6, the receiving apparatus 200 may include the receiver 210, the decoder 220, the processor 230, a deinterleaver 240, and an AV decoder 250.

The description of the receiver 210, the decoder 220, and the processor 230 of FIG. 3 may be applied to the receiver 210, the decoder 220, and the processor 230 of FIG. 6, and the overlapping description will not be further described.

The receiver 210 may receive a plurality of packets transmitted by the transmitting apparatus 100. The receiver 210 may obtain information on the symbols included in the payload from the packet header of each packet, information (i.e., SBN and ESI) and the parameters used in encoding (i.e., S₁ and S₂). The operation of the receiver 210 may be controlled by the processor 230.

The receiver 210 may output a symbol obtained from the packet to the deinterleaver 240.

The deinterleaver 240 may deinterleave symbols input from the receiver 210.

In this example, the deinterleaver 240 may deinterleave the symbols based on the deinterleaving rule corresponding to the interleaving rule of the transmitting apparatus 100, and may output the deinterleaved symbols to the decoder 220.

The decoder 220 may decode the symbols input from the deinterleaver 240. A decoding method is described in FIG. 3, and thus a detailed description thereof will be omitted.

The decoder 220 may output the source symbols recovered by the decoding to the AV decoder 250.

The AV decoder 250 may perform decoding on the source symbols. Specifically, the AV decoder 250 may decompress the source symbols and output the contents transmitted by the transmitting apparatus 100.

The processor 230 may transmit, to the transmitting apparatus 100, information on whether the decoding is successful, the SBN of the symbol, information on S1 and S2, and information on the bit rate at which the content is transmitted.

According to an embodiment, the transmitting apparatus 100 may have different code rate or number of symbols punctured according to the decoding success of the receiving apparatus. Accordingly, when the number of repair symbols received from the transmitting apparatus is adaptively changed according to a network situation, the receiving apparatus and transmitting apparatus may be able to reduce the network congestion and efficiently utilize the available bandwidth.

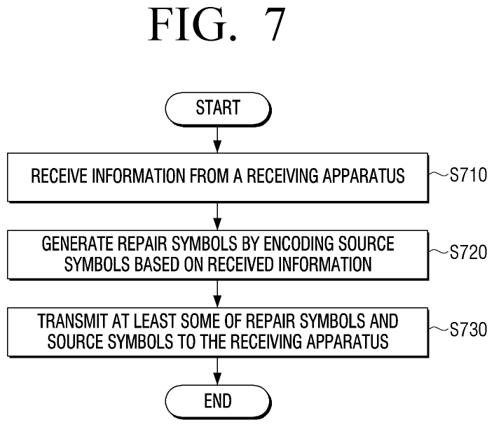

FIG. 7 is a flowchart illustrating a method for controlling a transmitting apparatus according to an embodiment.

First, information may be received from a receiving apparatus in operation S710. The received information may include information on whether the received symbols have been successfully decoded in the receiving apparatus.

By performing encoding of source symbols based on the received information, repair symbols may be generated in operation S720.

A part of the repair symbols and source symbols may be transmitted to the receiving apparatus in operation S730.

The number of repair symbols transmitted to the receiving apparatus may vary depending on whether the receiving apparatus is successfully decoded.

The operation S720 may include determining a parameter based on the received information, and encoding the source symbols based on a quasi-cyclic low density parity check (QC-LDPC) code having a code rate determined based on the parameter. Here, the parameter may include a row splitting coefficient defined in the QC-LDPC code.

The control method according to an embodiment may perform puncturing on repair symbols. In this example, performing the puncturing may include determining the number of symbols to be punctured based on the received information and performing puncturing based on the determined number.

In operation S730, the source symbols and repair symbols left after the puncturing may be transmitted to the receiving apparatus.

In operation S720, if the decoding is successful in the receiving apparatus, the parameter may be determined such that the number of repair symbols transmitted to the receiving apparatus is less than the threshold value, and if the decoding fails in the receiving apparatus, the parameter may be determined so that the number of repair symbols transmitted to the receiving apparatus is greater than before. If the decoding is successful in the receiving apparatus, the number of symbols to be punctured may be determined so that the number of repair symbols transmitted to the receiving apparatus is smaller than the previous number of repair symbols transmitted, and if the decoding fails in the receiving apparatus, the number of symbols to be punctured can be determined so that the number of repair symbols transmitted to the receiving apparatus is greater than before.

The receiving apparatus may decode the symbols received from the transmitting apparatus based on the first decoding algorithm, decode the symbols received from the transmitting apparatus based on a second decoding algorithm having superior performance than the first decoding algorithm when the decoding based on the first decoding algorithm fails, and transmit, to the transmitting apparatus, information on whether the decoding is successful based on the first decoding algorithm and the second decoding algorithm.

If decoding based on the first decoding algorithm is successful, it is possible to determine whether the number of previously punctured symbols satisfies a predetermined first condition. Here, the predetermined first condition may be a condition based on the number of maximum symbols that can be punctured.

In operation S720, if the predetermined first condition is satisfied, the parameter may be determined so that the code rate is higher than the previous code rate, and if the predetermined first condition is not satisfied, the parameter may be determined in the same manner as before. Also, the operation of performing puncturing may determine the number of symbols to be punctured to zero if a predetermined first condition is satisfied, and determine the number of symbols to be punctured such that more symbols are punctured than before if a predetermined first condition is not satisfied.

If decoding based on the first decoding algorithm and the second decoding algorithm fails, it is possible to determine whether the number of previously punctured symbols satisfies a predetermined second condition. Here, the second predetermined condition may be a condition based on the maximum number of symbols that can be punctured.

In operation S720, if a predetermined second condition is satisfied, the parameter may be determined so that the code rate is lower than before. Also, when the predetermined second condition is satisfied, the maximum number of symbols that can be punctured defined by determined parameter may be determined as the number of symbols to be punctured, and if the second predetermined condition is not satisfied, the number of symbols to be punctured can be determined so that fewer symbols are punctured than before.

In operation S720, if decoding based on the first decoding algorithm fails and decoding based on the second decoding algorithm is successful, encoding may be performed based on the same parameters as before. In addition, performing the puncturing may include determining the number of symbols to be punctured, as before, if the decoding based on the first decoding algorithm fails and the decoding based on the second decoding algorithm succeeds.

A method for determining the number of symbols to be punctured and the parameter used in encoding the transmitting apparatus has been described above.

According to various embodiments as described above, the number of repair symbols transmitted to the receiving apparatus may be adaptively changed according to the decoding success of the receiving apparatus, and transmission efficiency may be improved by minimizing transmission overhead without generating a fixed overhead.

In addition, various embodiments of the disclosure may be implemented in software, including instructions stored on machine-readable storage media readable by a machine (e.g., a computer). An apparatus may call instructions from the storage medium, and execute the called instruction, including an electronic apparatus according to the disclosed embodiments. When the instructions are executed by a processor, the processor may perform a function corresponding to the instructions directly or by using other components under the control of the processor. The instructions may include a code generated by a compiler or a code executable by an interpreter. A machine-readable storage medium may be provided in the form of a non-transitory storage medium. Herein, the term “non-transitory” only denotes that a storage medium does not include a signal but is tangible, and does not distinguish the case in which a data is semi-permanently stored in a storage medium from the case in which a data is temporarily stored in a storage medium.

According to an embodiment, the method according to the above-described embodiments may be provided as being included in a computer program product. The computer program product may be traded as a product between a seller and a consumer. The computer program product may be distributed online in the form of machine-readable storage media (e.g., compact disc read only memory (CD-ROM)) or through an application store (e.g., Play Store™ and App Store™) or distributed online (e.g., downloaded or uploaded) directly between to users (e.g., smartphones). In the case of online distribution, at least a portion of the computer program product may be at least temporarily stored or temporarily generated in a server of the manufacturer, a server of the application store, or a machine-readable storage medium such as memory of a relay server.

According to the embodiments, the respective elements (e.g., module or program) of the elements mentioned above may include a single entity or a plurality of entities. According to the embodiments, at least one element or operation from among the corresponding elements mentioned above may be omitted, or at least one other element or operation may be added. Alternatively or additionally, a plurality of components (e.g., module or program) may be combined to form a single entity. In this case, the integrated entity may perform functions of at least one function of an element of each of the plurality of elements in the same manner as or in a similar manner to that performed by the corresponding element from among the plurality of elements before integration. The module, a program module, or operations executed by other elements according to variety of embodiments may be executed consecutively, in parallel, repeatedly, or heuristically, or at least some operations may be executed according to a different order, may be omitted, or the other operation may be added thereto.

What is claimed is:

1. A transmitting apparatus comprising:
an encoder;
a transmitter; and
a processor configured to:
control the encoder to generate repair symbols by performing encoding of source symbols based on information received from a receiving apparatus, and
control the transmitter to transmit, to the receiving apparatus, the source symbols and at least some of the repair symbols,
wherein the information comprises information indicating whether a decoding of symbols received from the receiving apparatus is successful, the symbols including the source symbols and the repair symbols, and
wherein a number of repair symbols transmitted to the receiving apparatus varies according to whether the decoding of the receiving apparatus is successful.

2. The transmitting apparatus of claim 1, wherein the encoder is configured to encode the source symbols based on a quasi-cyclic low density parity check (QC-LDPC) code having a code rate determined based on a parameter,
the transmitter is configured to transmit, to the receiving apparatus, the source symbols and the at least some repair symbols left after performing a puncturing, and
the processor is further configured to:
determine the parameter based on the information, and control the encoder to perform the encoding based on the determined parameter,
determine a number of symbols to be punctured based on the information, and
perform the puncturing based on the determined number of symbols to be punctured.

3. The transmitting apparatus of claim 2, wherein the processor is further configured to:
based on the decoding at the receiving apparatus being successful, determine the parameter and the number of symbols to be punctured so that a second number of the at least some repair symbols to be transmitted to the receiving apparatus is less than a first number of the at least some repair symbols, the first number of the at least some repair symbols being transmitted prior to the second number of the at least some repair symbols, and
based on the decoding at the receiving apparatus failing, determine the parameter and the number of symbols to be punctured so that the second number of the at least some repair symbols to be transmitted to the receiving apparatus is greater than the first number of the at least some repair symbols.

4. The transmitting apparatus of claim 2, wherein the receiving apparatus is configured to decode the symbols received from the transmitting apparatus based on a first decoding algorithm, and based on the first decoding algorithm of the receiving apparatus failing to decode at least one symbol among the symbols, decode the at least one symbol based on a second decoding algorithm having a relatively superior performance than the first decoding algorithm, and transmit, to the transmitting apparatus, the information indicating whether at least one of the first decoding algorithm or the second decoding algorithm is successful in the decoding.

5. The transmitting apparatus of claim 4, wherein the processor is further configured to:
based on the decoding based on the first decoding algorithm being successful, identify whether a number of symbols punctured in previous symbols satisfies a predetermined first condition, and based on determining that the predetermined first condition is satisfied, determine the parameter and a number of symbols to be punctured for current symbols, and
wherein the predetermined first condition is a value obtained by summing the number of symbols punctured in the previous symbols and a predetermined value that is greater than a maximum number of puncturable symbols.

6. The transmitting apparatus of claim 5, wherein the processor is further configured to:
based on the predetermined first condition being satisfied, determine the parameter so that the code rate is higher than a code rate of the previous symbols, and set the number of symbols to be punctured to zero, and
based on the predetermined first condition not being satisfied, determine the parameter so that the code rate is lower than the code rate of the previous symbols and determine the number of symbols to be punctured to be larger than the number of symbols punctured in the previous symbols.

7. The transmitting apparatus of claim 4, wherein the processor is further configured to:
based the first decoding algorithm and the second decoding algorithm failing, identify whether a number of symbols punctured in previous symbols satisfies a predetermined second condition, and
determine the parameter and the number of symbols to be punctured based on whether the predetermined second condition is satisfied, and
wherein the predetermined second condition is a value obtained by subtracting a predetermined value from the number of symbols punctured in the previous symbols.

8. The transmitting apparatus of claim 7, wherein the processor is further configured to:
based on the predetermined second condition being satisfied, determine the parameter so that the code rate is lower than a code rate of the previous symbols,
determine a maximum number of puncturable symbols defined according to the determined parameter as the number of symbols to be punctured, and
based on the predetermined second condition not being satisfied, determine the number of symbols to be punctured to be fewer than the number of symbols punctured in the previous symbols.

9. The transmitting apparatus of claim 4, wherein the processor is further configured to, based on decoding based on the first decoding algorithm failing and decoding based on the second decoding algorithm being successful, control the encoder to perform encoding based on a parameter which is identical to a parameter used in previous symbols and determine a number of symbols to be punctured in a same manner as the previous symbols.

10. The transmitting apparatus of claim 2, wherein the parameter comprises a row splitting coefficient defined in the QC-LDPC code.

11. A method for controlling a transmitting apparatus, the method comprising:
receiving information from a receiving apparatus;
generating repair symbols by performing encoding of source symbols based on the received information; and
transmitting, to the receiving apparatus, the source symbols and at least some of the repair symbols,
wherein the received information comprises information indicating whether a decoding of symbols received from the receiving apparatus is successful, the symbols including the source symbols and the repair symbols, and
wherein a number of repair symbols transmitted to the receiving apparatus varies according to the decoding of the receiving apparatus being successful.

12. The method of claim 11, further comprising:
performing puncturing of the repair symbols,
wherein the generating the repair symbols comprises determining a parameter based on the received information, and encoding the source symbols based on a quasi-cyclic low density parity check (QC-LDPC) code having a code rate determined based on the parameter,
wherein the performing the puncturing comprises determining a number of symbols to be punctured based on the received information, and performing puncturing based on the determined number of symbols to be punctured, and
wherein the transmitting comprises transmitting, to the receiving apparatus, the source symbols and the at least some repair symbols left after performing the puncturing.

13. The method of claim 12, wherein the generating the repair symbols further comprises, based on the decoding at the receiving apparatus being successful, determining the parameter and the number of symbols to be punctured so that a second number of the at least some repair symbols to be transmitted to the receiving apparatus is less than a first number of the at least some repair symbols, the first number of the at least some repair symbols being transmitted to the receiving apparatus prior to the second number of the at least some repair symbols, and
based on the decoding at the receiving apparatus failing, determining the parameter and the number of symbols to be punctured so that the second number of the at least some repair symbols to be transmitted to the receiving apparatus is greater than the first number of the at least some repair symbols.

14. The method of claim 12, wherein the receiving apparatus is configured to:
decode the symbols received from the transmitting apparatus based on a first decoding algorithm, and based on the first decoding algorithm of the receiving apparatus failing to decode at least one symbol among the symbols, decode the at least one symbol based on a second decoding algorithm having a relatively superior performance than the first decoding algorithm, and transmit, to the transmitting apparatus, the information indicating whether at least one of the first decoding algorithm or the second decoding algorithm is successful in the decoding.

15. The method of claim 14, further comprising:
based on the decoding based on the first decoding algorithm being successful, identifying whether a number of symbols punctured in previous symbols satisfies a predetermined first condition,
wherein the predetermined first condition is a value obtained by summing the number of symbols punctured in the previous symbols and a predetermined value that is greater than a maximum number of puncturable symbols.

16. The method of claim 15, wherein the generating the repair symbols further comprises,
based on the predetermined first condition being satisfied, determining the parameter so that the code rate is higher than a code rate of the previous symbols, and based on the predetermined first condition not being satisfied, determining the parameter in a same manner as the previous symbols,
wherein the performing puncturing comprises, based on the predetermined first condition being satisfied, setting the number of symbols to be punctured to zero, and based on the predetermined first condition not being satisfied, determining the number of symbols to be punctured to be larger than the number of symbols punctured in the previous symbols.

17. The method of claim 14, further comprising:
based on the first decoding algorithm and the second decoding algorithm failing to decode the symbols, identifying whether a number of symbols punctured in previous symbols satisfies a predetermined second condition,
wherein the predetermined second condition is a value obtained by subtracting a predetermined value from the number of symbols punctured in the previous symbols.

18. The method of claim 17, wherein the generating the repair symbols further comprises, based on the predetermined second condition being satisfied, determining the parameter so that the code rate is lower than a code rate of the previous symbols, and
wherein the performing puncturing comprises, based on the predetermined second condition being satisfied, determining a maximum number of puncturable symbols defined according to the determined parameter as the number of symbols to be punctured and based on the predetermined second condition not being satisfied, determining the number of symbols to be punctured to be less than the number of symbols punctured in the previous symbols.

19. The method of claim 14, wherein the generating the repair symbols further comprises, based on decoding based on the first decoding algorithm failing and decoding based on the second decoding algorithm being successful, performing the encoding based on a parameter which is identical a parameter used in previous symbols, and
wherein the performing puncturing comprises, based on decoding based on the first decoding algorithm failing and decoding based on the second decoding algorithm being successful, determining a number of symbols to be punctured in a same manner as the previous symbols.

20. The method of claim 12, wherein the parameter comprises a row splitting coefficient defined in the QC-LDPC code.
